(19) United States
(12) Patent Application Publication
(10) Pub. No.: US 2015/0062827 A1
(43) Pub. Date: Mar. 5, 2015

(54) HEAT SINK AND SUBSTRATE UNIT

(71) Applicant: FUJITSU LIMITED, Kawasaki-shi (JP)

(72) Inventors: Osamu Aizawa, Kashiwa (JP); Tsuyoshi So, Kawasaki (JP); Eiji Makabe, Kawasaki (JP); Yoshinori Uzuka, Kawasaki (JP)

(21) Appl. No.: 14/326,628

(22) Filed: Jul. 9, 2014

(30) Foreign Application Priority Data
Aug. 30, 2013 (JP) 2013-179771

(51) Int. Cl. H05K 7/20; F28F 13/00

(52) U.S. Cl. CPC H05K 7/2049; F28F 13/00; F28F 2215/00
USPC 361/720; 165/185

(57) ABSTRACT

A heat sink includes: a fixing unit fixed to a heating element; and a heat dissipation unit including a heat dissipation protruding portion and configured to slide with respect to the fixing unit.

### CROSS-REFERENCE TO RELATED APPLICATIONS

This application is based upon and claims the benefit of priority from the prior Japanese Patent Application No. 2013-179771 filed on Aug. 30, 2013, the entire contents of which are incorporated herein by reference.

### FIELD

The present disclosure relates to a heat sink and a substrate unit.

### BACKGROUND

A heat sink includes a fixing unit fixed to a heating element, and heat dissipation protruding portions formed integrally with the fixing unit.

A related technology is disclosed in Japanese Laid-Open Patent Publication Nos. 2010-219250, 2010-263118 and 2007-188998.

### SUMMARY

According to one aspect of the embodiments, a heat sink includes: a fixing unit fixed to a heating element; and a heat dissipation unit including a heat dissipation protruding portion and configured to slide with respect to the fixing unit.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 illustrates an exemplary side cross-sectional view of a substrate unit.

FIG. 2 illustrates an exemplary position change of a heat dissipation unit.

FIG. 3 illustrates an exemplary exploded perspective view of a heat sink.

FIG. 4 illustrates an exemplary cross-sectional view taken along a line 4-4 of the heat sink.

FIG. 5 illustrates an exemplary position change of a heat dissipation unit.

FIG. 6 illustrates an exemplary heat sink.

FIG. 7 illustrates an exemplary cross-sectional view of a heat sink.

FIG. 8 illustrates an exemplary perspective view of a heat sink.

FIG. 9 illustrates an exemplary side cross-sectional view of a substrate unit.

FIG. 10 illustrates an exemplary position change of an electronic component.

### DESCRIPTION OF EMBODIMENTS

In a technology of cooling a heating element by using a heat sink, a restriction may be imposed on placement of a heating element such as an electronic component with respect to a heat sink, for example, when the heating element is disposed at a desired position on a printed circuit board.

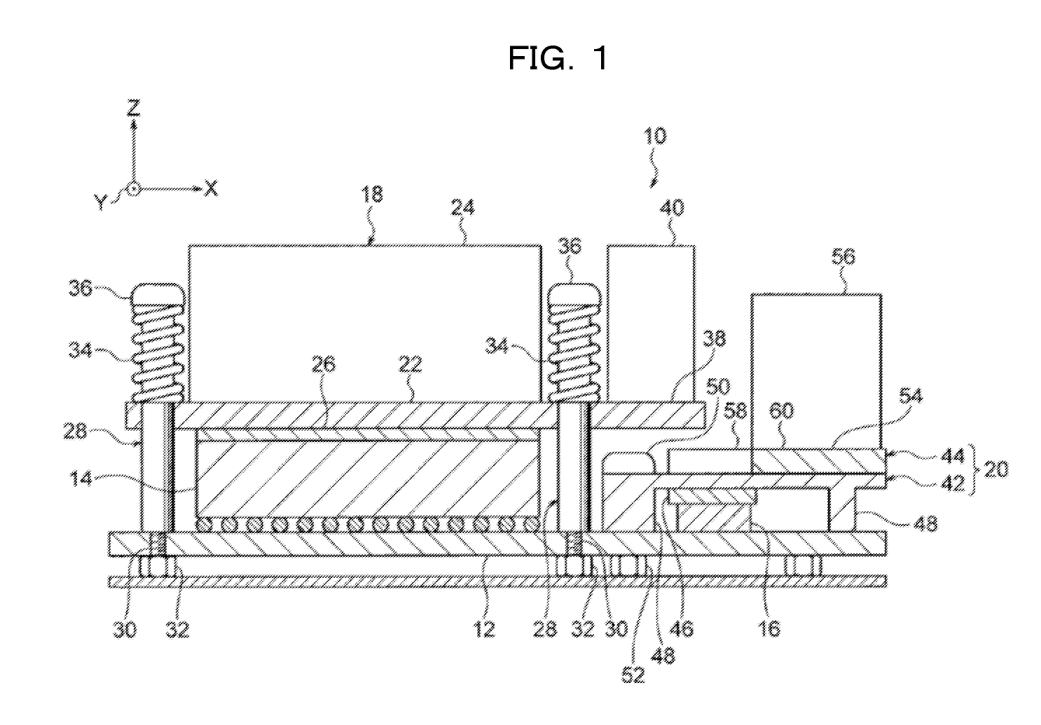

FIG. 1 illustrates an exemplary side cross-sectional view of a substrate unit. The substrate unit 10 illustrated in FIG. 1 includes a printed circuit board 12, a plurality of electronic components 14 and 16, and a plurality of heat sinks 18 and 20. The electronic component 14 may also be referred to as a first electronic component 14, and the electronic component 16 may also be referred to as a second electronic component 16.

The printed circuit board 12 is formed in a flat plate shape. Each of the first and second electronic components 14 and 16 is mounted on the surface of the printed circuit board 12 by, for example, soldering. The first and second electronic components 14 and 16 may be, for example, heating components such as a central processing unit (CPU), and may be aligned in the X direction when the printed circuit board 12 extends in the X direction and the Y direction.

The first and second electronic components 14 and 16 are coupled to each other through a wiring (e.g., conductive pattern) formed on the surface of the printed circuit board 12 so that transmission and reception of signals are performed between the first electronic component 14 and the second electronic component 16. For example, the first electronic component 14 at one side may be a first heating element, and the second electronic component 16 at the other side may be a second heating element.

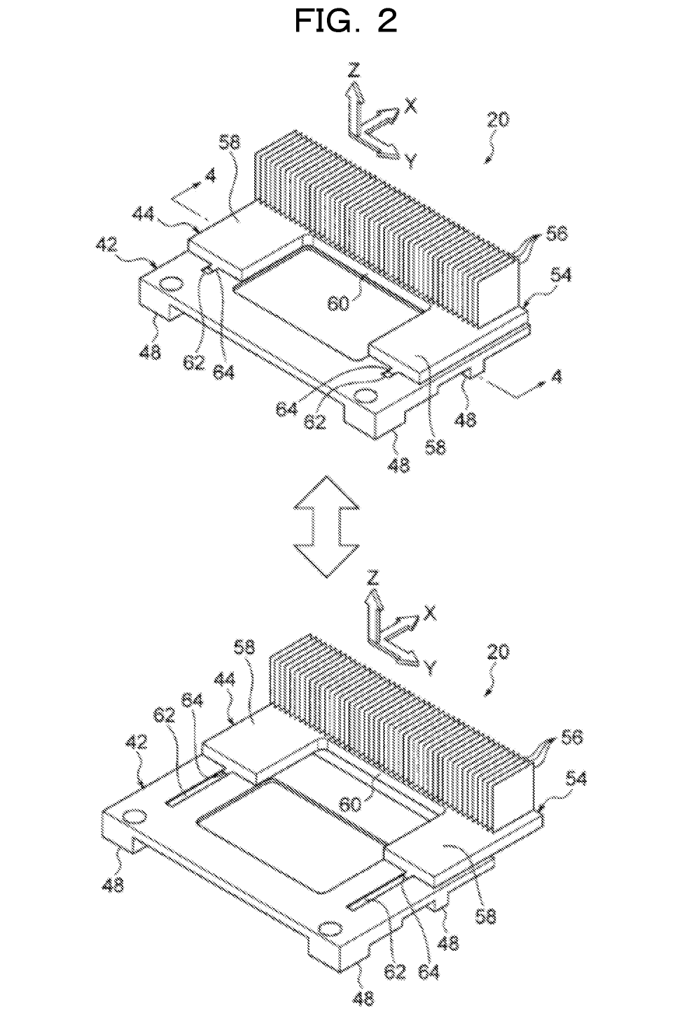

Both of the heat sinks 18 and 20 are made of a metallic material such as an aluminum alloy which is excellent in heat dissipation and thermal conductivity. The heat sink 18 at one side may be an exemplary first heat sink (hereinafter, the heat sink 18 may also be referred to as a first heat sink 18), and includes a plate-shaped fixing unit 22, and a plurality of fins 24 vertically provided on the surface of the fixing unit 22. Each of the fins 24 is formed in a plate shape which has a plate thickness in the Y direction and extends in the X direction. The plurality of fins 24 are arranged in the Y direction to be spaced apart from each other, in the same manner as a plurality of fins 56 (See, e.g., FIG. 2) provided on the heat sink 20 at the other side.

The fixing unit 22 is superimposed on the surface of the first electronic component 14 through a heat transfer sheet 26. Stepped screws 28 penetrate portions of the fixing unit 22 at both sides of the first electronic component 14, respectively. A threaded portion 30 formed on the end portion of each stepped screw 28 penetrates the printed circuit board 12 from the front side of the printed circuit board 12, and a nut 32 is screwed on the end portion of the threaded portion 30 from the rear side of the printed circuit board 12.

A coil spring 34 is fitted on the stepped screw 28, and is interposed between a head portion 36 of the stepped screw 28 and the fixing unit 22 in a compressed state. The fixing unit 22 is forcedly pressed toward the side of the first electronic component 14 by the coil spring 34. In a state where the fixing unit 22 is forcedly pressed toward the side of the first electronic component 14, the first heat sink 18 is fixed to the first electronic component 14.

An extension portion 38 is formed at the end portion of the fixing unit 22 of the first heat sink 18 on the side of the second electronic component 16. The extension portion 38 may be formed by extending the end portion of the fixing unit 22 on the side of the second electronic component 16 along the X direction to the side of the second electronic component 16. A plurality of fins 40 similar to the plurality of fins 24 are vertically provided on the surface of the extension portion 38.

The other heat sink 20 may be an exemplary second heat sink, and includes a fixing unit 42, and a heat dissipation unit 44 (hereinafter, the other heat sink 20 may also be referred to as a second heat sink 20). The fixing unit 42 and the heat dissipation unit 44 may be separate members. The fixing unit 42 is formed in a plate shape, and is superimposed on the surface of the second electronic component 16 through a heat transfer sheet 46. Leg portions 48 are formed on the fixing unit 42 at both sides of the second electronic component 16, respectively, to extend toward the printed circuit board 12. Each leg portion 48 is in contact with the surface of the printed circuit board 12 and is vertically provided on the printed circuit board 12.

A screw 50 penetrates the leg portion 48 positioned on the side of the first electronic component 14 and a portion of the printed circuit board 12 corresponding to the leg portion 48, from the front side of the fixing unit 42. A nut 52 is screwed on the end portion of the screw 50 from the rear side of the printed circuit board 12. The fixing unit 42 is fixed to the second electronic component 16 by the screw 50.

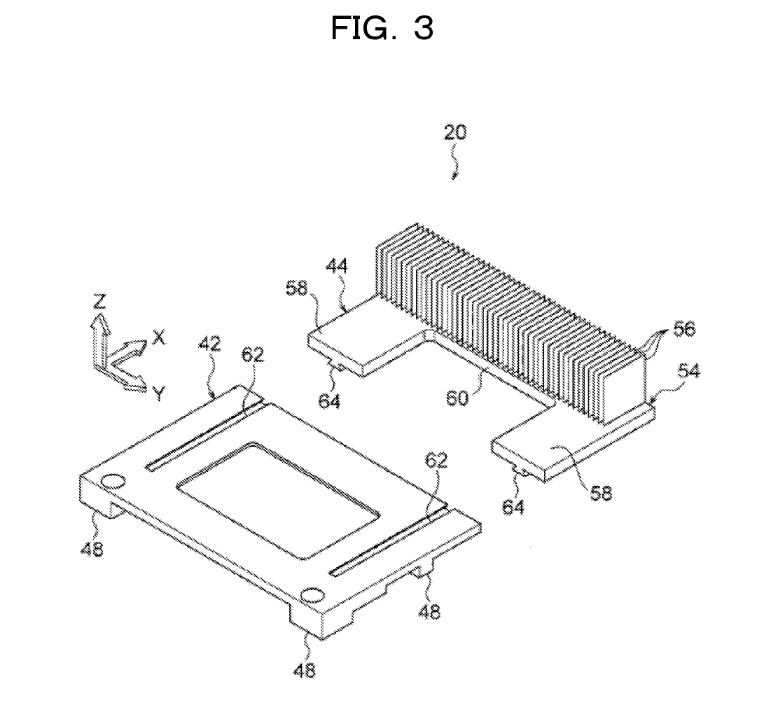

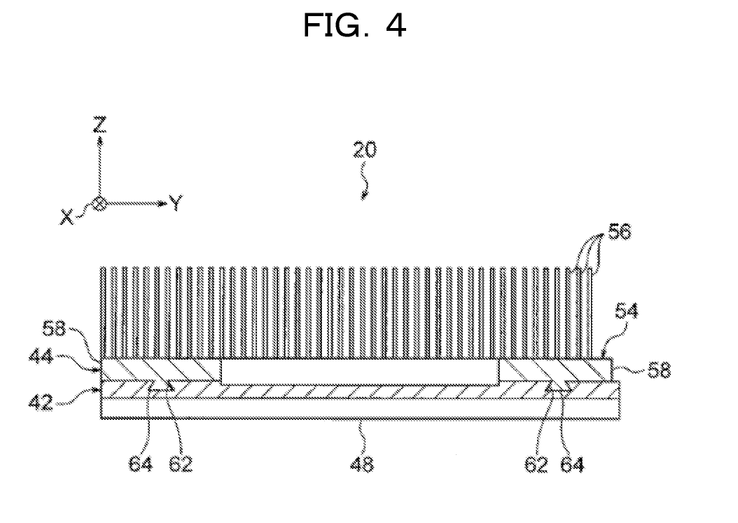

The heat dissipation unit 44 includes a main body 54 having a plate shape superimposed on the surface of the fixing unit 42, and a plurality of fins 56 vertically provided on the surface of the main body 54 (on the surface at a side opposite to the fixing unit 42). FIG. 2 illustrates an exemplary position change of a heat dissipation unit. FIG. 2 illustrates the states of the heat dissipation unit of the heat sink illustrated in FIG. 1 before and after the position thereof is changed by perspective views. FIG. 3 illustrates an exemplary heat sink. FIG. 3 illustrates an exploded perspective view of the heat sink illustrated in FIG. 2. FIG. 4 illustrates an exemplary cross-sectional view of the heat sink. FIG. 4 illustrates a cross-sectional view taken along a line 4-4 of the heat sink 20 illustrated in FIG. 2. As illustrated in FIGS. 2 and 3, the main body 54 includes a pair of arm portions 58 which extend in the X direction and are arranged in parallel to each other in the Y direction, and a connection portion 60 which extends in the Y direction to interconnect one ends of the pair of arm portions 58.

Each of the fins 56 is formed in a plate shape which has a plate thickness in the Y direction and extends in the X direction. The plurality of fins 56 are arranged in the Y direction to be spaced apart from each other. The plurality of fins 56 may be exemplary heat dissipation protruding portions, and may be provided on the connection portion 60 of the main body 54. For example, as illustrated in FIG. 1, the plurality of fins 56 are provided on the main body 54 at a side opposite to the extension portion 38 side which is at one side in the X direction.

As illustrated in FIG. 3, a pair of grooves 62 are formed in the fixing unit 42 to be opened on the surfaces of the fixing unit 42. The pair of grooves 62 extend in the X direction and are formed in the fixing unit 42 at both end portions in the Y direction. One end of each of the grooves 62 is terminated, and the other end of each of the grooves 62 is opened in the X direction of the fixing unit 42. The X direction where the pair of grooves 62 extend may intersect the Z direction where the fixing unit 42 is superimposed on the second electronic component 16 (see FIG. 1).

A pair of projecting portions 64 are formed on the rear surface of the heat dissipation unit 44 to protrude toward the fixing unit 42. The pair of projecting portions 64 are formed at positions corresponding to the pair of grooves 62, respectively, and extend in the X direction, respectively, like the pair of grooves 62.

The pair of projecting portions 64 are inserted into the pair of grooves 62 form the other end sides of the pair of grooves 62. Each groove 62 and each projecting portion 64 are formed in tapered shapes in which the width of the Y direction is decreased from the bottom side of the groove 62 to the opening side of the groove 62. This suppresses the projecting portion 64 from being released from the groove 62. When the pair of projecting portions 64 are inserted into the pair of grooves 62, the heat dissipation unit 44 is slidable in the X direction with respect to the fixing unit 42. As illustrated in FIG. 1, for example, the sliding direction of the heat dissipation unit 44 may correspond to the extension direction of the extension portion 38.

In a state where the second heat sink 20 and the first heat sink 18 are aligned in the X direction, the extension portion 38 of the first heat sink 18 covers a part of the fixing unit 42 of the second heat sink 20. For example, the extension portion 38 is positioned at a higher position than the fixing unit 42 in the height direction of the heat sink 20 (in the Z direction), while overlapping with a part of the fixing unit 42 on the side of the first electronic component 14 in the X direction.

The extension portion 38 is positioned at a higher position than the main body 54 in the height direction of the heat sink 20. The heat dissipation unit 44 may be slid to the opposite side to the side of the extension portion 38 so as to avoid for the fins 56 of the heat dissipation unit 44 interfering with the extension portion 38. Accordingly, the fins 56 are disposed to be offset from the second electronic component 16 in the X direction which is the sliding direction of the heat dissipation unit 44.

Even though the extension portion 38 is formed in the heat sink 18 illustrated in FIG. 1, the positions of the first electronic component 14 and the second electronic component 16 are unchanged, and only the position of the heat dissipation unit 44 is moved to the opposite side to the side of the first electronic component 14. A moving mechanism is provided to correspond to the addition of the extension portion 38.

A heat transfer material such as, a thermal grease, may be interposed between the heat dissipation unit 44 and the fixing unit 42 so as to facilitate heat transfer.

In the substrate unit illustrated in FIG. 1, the heat dissipation unit 44 is slid with respect to the fixing unit 42. Even though the extension portion 38 which extends to the side of the second electronic component 16 is formed in the heat sink 18 to improve the heat dissipation, the heat dissipation unit 44 is slid with respect to the fixing unit 42 to the side opposite to the extension portion 38. Therefore, the interference of the extension portion 38 with the fins 56 of the heat dissipation unit 44 may be reduced. The placement restriction imposed on the second electronic component 16 may be decreased so that the second electronic component 16 may be disposed close to the first electronic component 14.

For example, when the heat sink 20 is formed as an integrated structure, together with the fixing unit 42 and the heat dissipation unit 44, the entire heat sink 20 including the heat dissipation unit 44 may be separated from the extension portion 38 so as to reduce the interference between the extension portion 38 extending from the heat sink 18 and the fins 56 of the heat dissipation unit 44. In this case, in order to secure the cooling property of the second electronic component 16, the second electronic component 16 may be disposed just below the second heat sink 20. For example, when the heat sink 20 is formed as an integrated structure, together with the fixing unit 42 and the heat dissipation unit 44, a placement restriction may be imposed on the second electronic component 16 since the second electronic component 16 is not disposed close to the first electronic component 14.

For example, when the heat dissipation unit 44 is slid with respect to the fixing unit 42 to the side opposite to the extension portion 38, the second electronic component 16 may be disposed close to the first electronic component 14.

When the first electronic component 14 is disposed close to the second electronic component 16, the length of wiring that interconnects the first electronic component 14 and the second electronic component 16 is reduced. Therefore, the transmission rate of a signal between the first electronic component 14 and the second electronic component 16 may be improved. Since the space below the extension portion 38 is effectively utilized for disposition of the second electronic component 16, the mounting density of the printed circuit board 12 may be improved.

The main body 54 of the heat dissipation unit 44 is superimposed on the fixing unit 42. Accordingly, the contact area between the fixing unit 42 and the heat dissipation unit 44 may be secured such that the thermal conductivity may be secured between the fixing unit 42 and the heat dissipation unit 44. Even when the heat dissipation unit 44 is slid with respect to the fixing unit 42, the heat dissipation of the heat sink 20 may be secured.

As illustrated in FIG. 2, the pair of grooves 62 extending in the X direction are formed in the fixing unit 42 and the projecting portions 64 inserted into the pair of grooves 62 are formed on the heat dissipation unit 44. Accordingly, the sliding direction of the heat dissipation unit 44 with respect to the fixing unit 42 is defined by the pair of grooves 62 and the projecting portions 64. Therefore, the operability when the heat dissipation unit 44 is slid, for example, the usability of the heat sink 20 may be improved.

As illustrated in FIG. 1, the leg portions 48 are formed on the fixing unit 42 to be vertically provided on the printed circuit board 12 at both sides of the second electronic component 16. The fixing unit 42 is supported on the printed circuit board 12 by the leg portions 48 at both sides of the second electronic component 16. Accordingly, even though the fixing unit 42 is fixed to the printed circuit board 12 by the screws 50, the load acting on the second electronic component 16 from the fixing unit 42 may be reduced.

The substrate unit 10 may include the first and second electronic components 14 and 16 as examples of a first heating element and a second heating element. Further, the substrate unit 10 may include heating components other than the electronic components, as examples of the first heating element and the second heating element.

The heat sink 20 may include the fins 56 as an exemplary heat dissipation protruding portions. For example, the heat sink 20 may include protruding portions formed in any shape other than fins, as the heat dissipation protruding portions. For example, the heat sink 18 may include protruding portions formed in any shape other than fins, as the heat dissipation protruding portions.

The heat dissipation unit 44 may be slidable in the extension direction (in the X direction) of the extension portion 38. For example, the heat dissipation unit 44 may be slidable in a different direction from the extension direction of the extension portion 38, such as in the Y direction, or in a direction where the X direction and the Y direction are combined with each other.

The grooves 62 may be formed in the fixing unit 42, and the projecting portions 64 may be formed on the heat dissipation unit 44. For example, the projecting portions 64 may be formed on the fixing unit 42 and the grooves 62 may be formed in the heat dissipation unit 44.

The leg portions 48 may be formed integrally with the fixing unit 42. Alternatively, the leg portions 48 may be formed as separate members from the fixing unit 42.

The substrate unit 10 may include the second electronic component 16 as an exemplary heating element. For example, the substrate unit 10 may include anything other than the second electronic component 16, as the heating element.

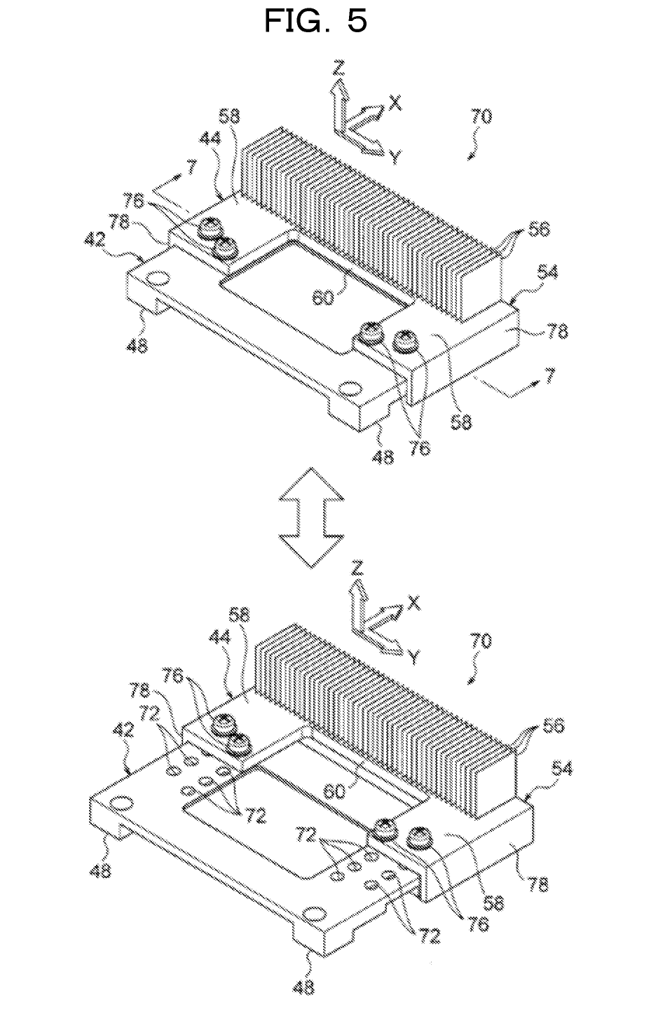

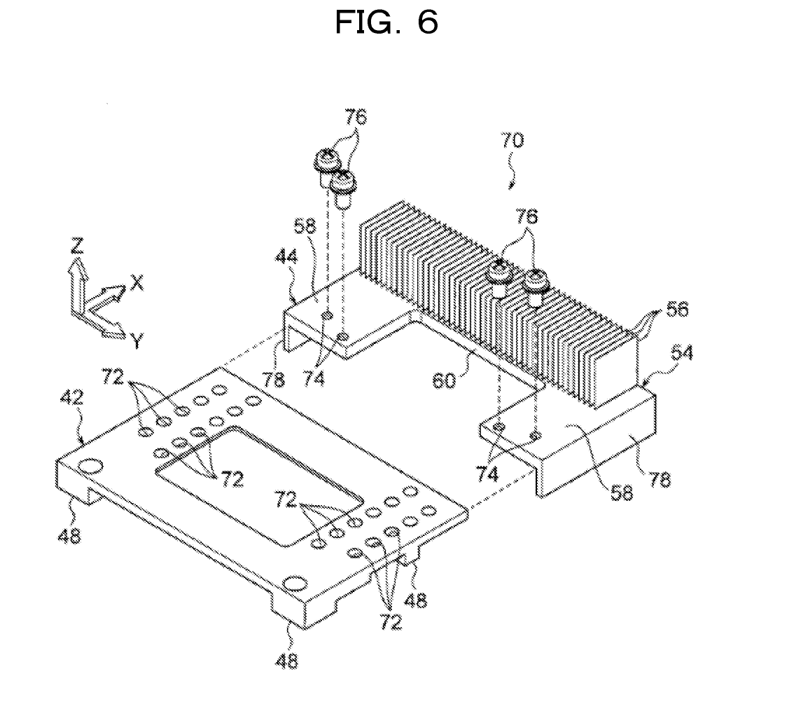

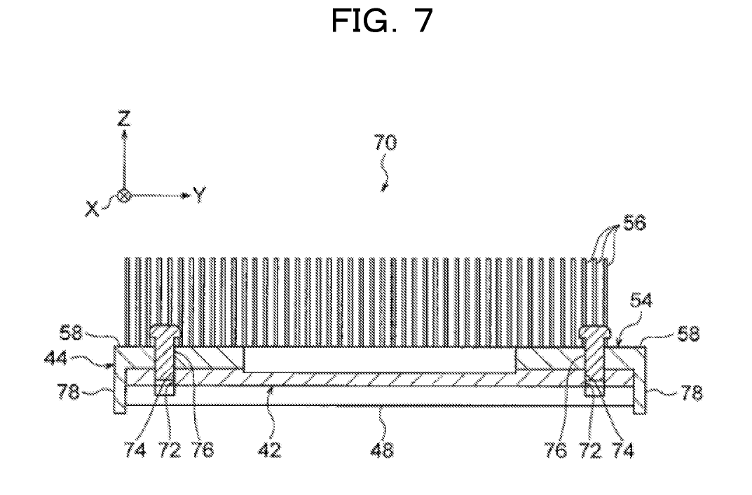

FIG. 5 illustrates an exemplary position change of a heat dissipation unit. FIG. 5 illustrates the states of the heat dissipation unit of a heat sink before and after the position thereof is changed by perspective views. FIG. 6 illustrates an exemplary heat sink. FIG. 6 illustrates an exploded perspective view of the heat sink illustrated in FIG. 5. FIG. 7 illustrates an exemplary cross-sectional view of a heat sink. FIG. 7 illustrates a cross-sectional view taken along the line 7-7 of the heat sink 70 illustrated in FIG. 5. The structure of the heat sink 70 illustrated in FIG. 5 may be different from the structure of the heat sink 20 illustrated in FIG. 2.

For example, as illustrated in FIG. 6, a plurality of screw holes 72 are formed in both end portions of the fixing unit 42 in the Y direction. The plurality of screw holes 72 formed in each of the end portions of the fixing unit 42 are aligned in two rows. The plurality of screw holes 72 in each row are aligned in the X direction in which the heat dissipation unit 44 is slid. The plurality of screw holes 72 in one row and the plurality of screw holes 72 in the other row in each end portion are arranged alternately. The number of the screw holes 72 may be optional.

Communication holes 74 are formed in the end portion of each of the arm portions 58 in the heat dissipation unit 44, for example, in the end portion opposite to the side of the connection portion 60. The communication holes 74 are selectively communicated with any of the plurality of screw holes 72 according to the sliding position of the heat dissipation unit 44 with respect to the fixing unit 42. Metallic screws 76 which are exemplary fixing members are inserted into the communication holes 74 from the side of the heat dissipation unit 44. When the front end portions of the screws 76 are screwed into the screw holes 72, the heat dissipation unit 44 may be fixed to the fixing unit 42 while being positioned with respect to the fixing unit 42 in the X direction (see, e.g., FIG. 7).

A pair of side wall portions 78 hanging down to the side of the fixing unit 42 are formed at both end portions of the heat dissipation unit 44 in the Y direction. The pair of side wall portions 78 extend in the X direction along both side portions of the fixing unit 42.

A heat transfer material such as, a thermal grease may be interposed between the heat dissipation unit 44 and the fixing unit 42 so as to facilitate heat transfer.

In the heat sink illustrated in FIGS. 5 to 7, the communication holes 74 are selectively communicated with any of the plurality of screw holes 72 according to the sliding position of the heat dissipation unit 44 with respect to the fixing unit 42. By inserting the screws 76 into the communication holes 74 and screwing the end portions of the screws 76 into the screw holes 72, the heat dissipation unit 44 may be fixed to the fixing unit 42 while being positioned with respect to the fixing unit 42. Therefore, the sudden movement of the heat dissipation unit 44 with respect to the fixing unit 42 may be suppressed.

Since the heat dissipation unit 44 and the fixing unit 42 are coupled through the metallic screws 76, heat may be transferred from the fixing unit 42 to the heat dissipation unit 44 through the screws 76. Therefore, the heat dissipation of the heat sink 70 may be improved.

Since the heat dissipation unit 44 is forcedly pressed against the fixing unit 42 through the screws 76, the adhesion between the heat dissipation unit 44 and the fixing unit 42 may be increased. Therefore, the heat dissipation of the heat sink 70 may be improved.

The pair of side wall portions 78 are formed on the heat dissipation unit 44 to extend in the sliding direction of the heat dissipation unit 44 along the both side portions of the fixing unit 42. The sliding direction of the heat dissipation unit 44 is defined with respect to the fixing unit 42 by the pair of side wall portions 78. Therefore, the operability when the heat dissipation unit 44 is slid, for example, the usability of the heat sink 70 may be improved.

The plurality of screw holes 72 may be formed in the fixing unit 42 to be aligned in the sliding direction of the heat dissipation unit 44, and the communication holes 74 may be formed in the heat dissipation unit 44. Further, the plurality of screw holes 72 may be formed in the heat dissipation unit 44, and the communication holes 74 may be formed in the fixing unit 42. By inserting the screws 76 into the communication holes 74 formed in the fixing unit 42 from the fixing unit 42 side and screwing the end portions of the screws 76 into the screw holes 72 formed in the heat dissipation unit 44, the heat dissipation unit 44 may be fixed to the fixing unit 42.

For example, the screw holes 72 and the screws 76 may be used as fixing holes and fixing members. Further, any other components besides the screw holes and the screws such as press-fit holes and press-fit members to be press-fitted into the press-fit holes, may be used as fixing holes and fixing members.

The pair of side wall portions 78 may be formed on the heat dissipation unit 44. Further, the pair of side wall portions 78 may be formed on the fixing unit 42 along both side portions of the heat dissipation unit 44.

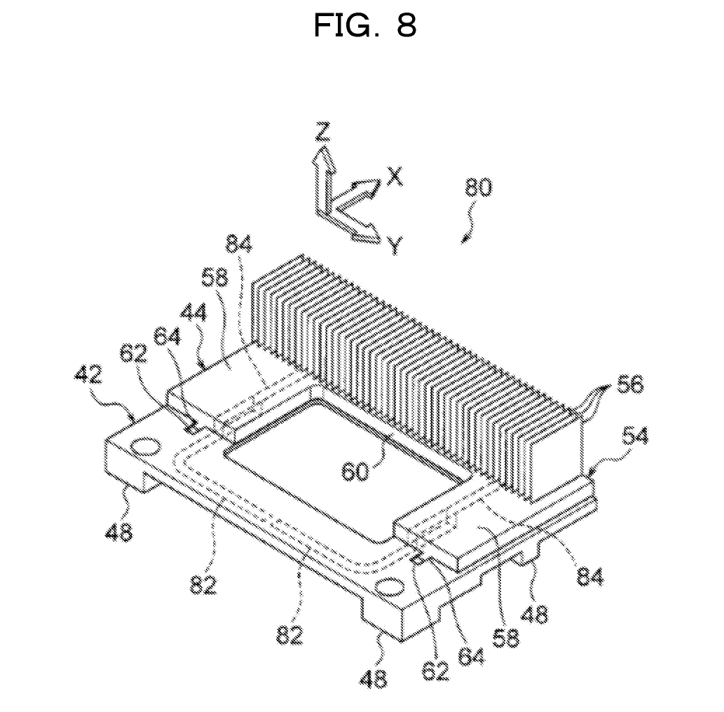

FIG. 8 illustrates an exemplary perspective view of a heat sink. The structure of the heat sink 80 illustrated in FIG. 8 may be different from the structure of the heat sink 20 illustrated in FIG. 2.

For example, a heat pipe 82 is provided in the fixing unit 42, and a heat pipe 84 is provided in the heat dissipation unit 44. Each of the heat pipes 82 and 84 includes at least one portion which extends in the X direction in which the heat dissipation unit 44 is slid. The portion of the heat pipe 82 which extends in the X direction, and the portion of the heat pipe 84 which extends in the X direction may be formed so as to maintain the overlapping state with each other in the X direction regardless of the sliding position of the heat dissipation unit 44.

Through this configuration, heat may be transferred by the heat pipes 82 and 84 besides the metal portions of the fixing unit 42 and the heat dissipation unit 44. Therefore, the heat dissipation of the heat sink 80 may be improved.

The heat pipes 82 and 84 may be provided in the fixing unit 42 and the heat dissipation unit 44, respectively. For example, a heat pipe may be provided in any one of the fixing unit 42 and the heat dissipation unit 44.

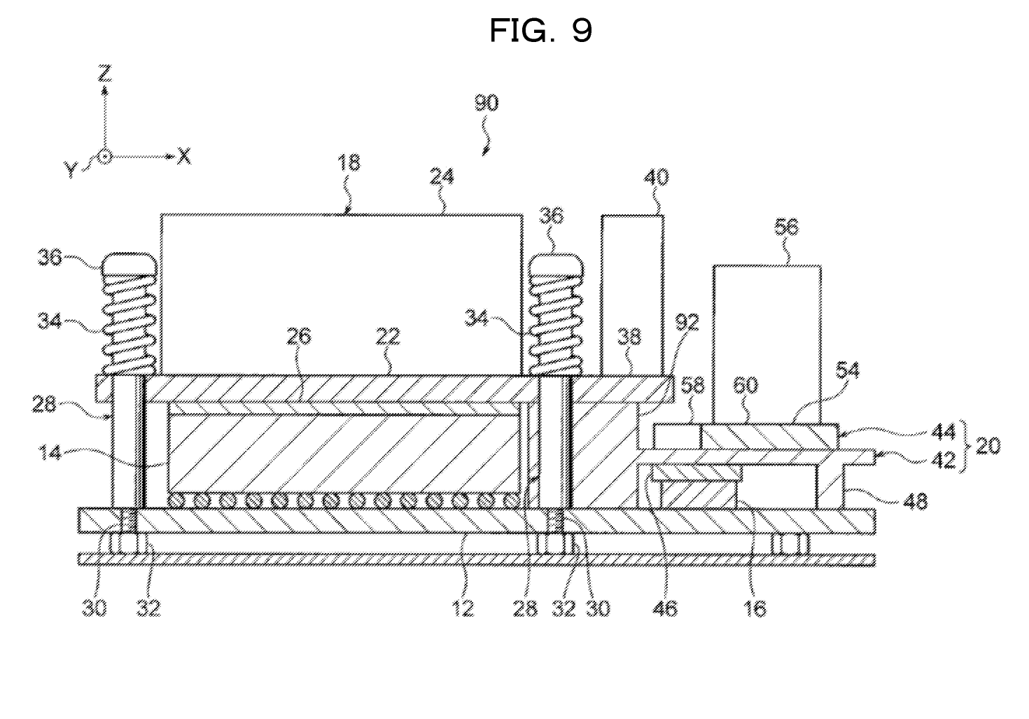

FIG. 9 illustrates an exemplary side cross-sectional view of a substrate unit. The structure of a substrate unit 90 illustrated in FIG. 9 may be different from the structure of the substrate unit 10 illustrated in FIG. 1.

For example, a connection portion 92 is formed at the end of the heat sink 20 at the side of the first electronic component 14. The connection portion 92 extends in the height direction of the heat sink 20, and the top surface of the connection portion 92 is in contact with the bottom surfaces of the fixing unit 22 and the extension portion 38. One stepped screw 28, as an exemplary fixture, penetrates the fixing unit 22 and the connection portion 92. By the common stepped screw 28, the fixing unit 42 of the heat sink 20 is fixed to the printed circuit board 12, together with the heat sink 18.

Through this configuration, as compared to a case where each of the heat sinks 18 and 20 is independently fixed to the printed circuit board 12, the number of fixing members (screws) may be reduced. When the number of fixing members is reduced, a space above the printed circuit board 12 is secured, thereby improving the mounting density of the printed circuit board 12.

Since the connection portion 92 formed on the fixing unit 42 is in contact with the fixing unit 22 and the extension portion 38 of the heat sink 18, heat may be transferred from one side to the other side of the heat sink 18 and the heat sink 20. Therefore, a cooling property of both the first and second electronic components 14 and 16 may be improved.

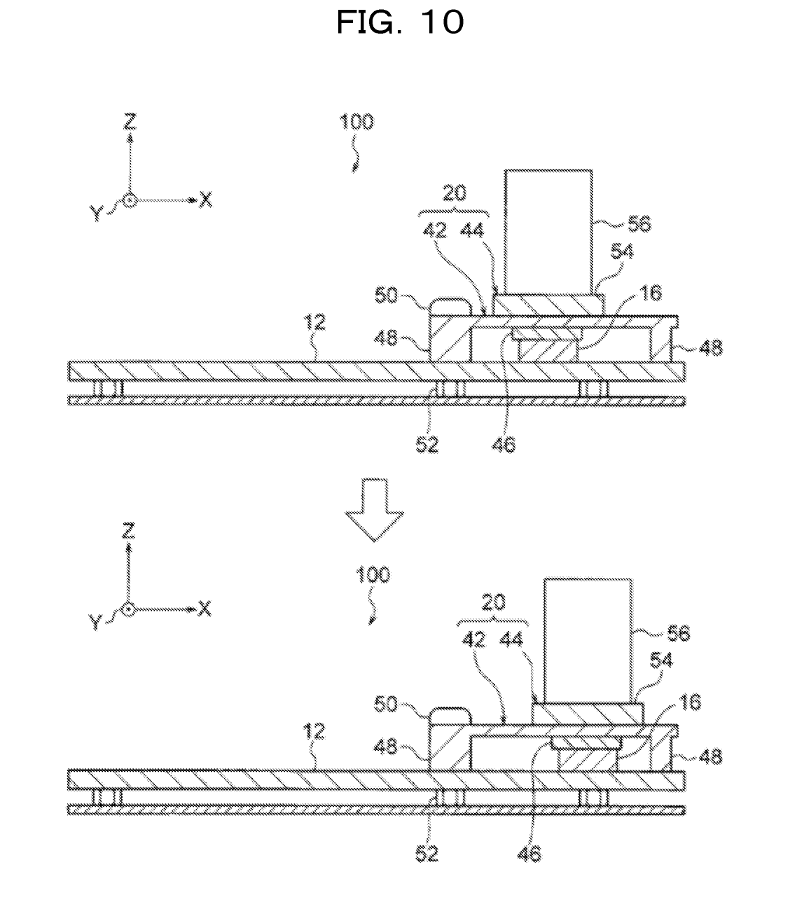

FIG. 10 illustrates an exemplary position change of an electronic component. FIG. 10 illustrates the states of the electronic component of the substrate unit before and after the position thereof is changed by side cross-sectional views. The structure of a substrate unit 100 illustrated in FIG. 10 may be different from the structure of the substrate unit 10 illustrated in FIG. 1.

In the upper drawing of FIG. 10, the state before a position of the second electronic component 16 in the substrate unit 100 is changed is illustrated. In the lower drawing of FIG. 10, the state after a position of the second electronic component 16 in the substrate unit 100 is changed is illustrated. For example, according to the specification change of the printed circuit board 12, as illustrated in the lower drawing of FIG. 10, the position of the second electronic component 16 is moved in the X direction.

According to the position change of the second electronic component 16, the heat dissipation unit 44 is also slid with respect to the fixing unit 42 in the X direction. A plurality of fins 56 formed on the heat dissipation unit 44 overlap with the second electronic component 16 in the X direction in which the heat dissipation unit 44 is slid.

Even when the position of the second electronic component 16 is changed, the plurality of fins 56 overlap with the second electronic component 16 because the heat dissipation unit 44 is slid. Thus, a cooling property of the second electronic component 16 may be secured.

Since the heat dissipation unit 44 is slid with respect to the fixing unit 42, the placement restriction imposed on the second electronic component 16 may be decreased. Thus, the placement flexibility of the second electronic component 16 may be secured and the mounting density of the printed circuit board 12 may be improved.

The above described exemplary embodiments may be properly combined with each other.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has (have) been described in detail, it should be understood that the various changes, substitutions, and alterations could be made hereto without departing from the spirit and scope of the invention.

What is claimed is:

1. A heat sink comprising:
a fixing unit fixed to a heating element; and
a heat dissipation unit including a heat dissipation protruding portion and configured to slide with respect to the fixing unit.

2. The heat sink of claim 1, wherein the fixing unit is fixed to be superimposed on the heating element, and the heat dissipation unit slide in an intersecting direction with respect to a direction in which the fixing unit is superimposed on the heating element.

3. The heat sink of claim 2, wherein the heat dissipation unit includes a main body superimposed on the fixing unit, and the heat dissipation protruding portions are vertically provided on the main body.

4. The heat sink of claim 3, wherein the heat dissipation protruding portions are formed on one side of the main body in the intersecting direction.

5. The heat sink of claim 1, wherein at least one groove which extends in an intersecting direction is formed in one of the fixing unit and the heat dissipation unit, and at least one projecting portion inserted into the groove is formed on the other of the fixing unit and the heat dissipation unit.

6. The heat sink of claim 5, wherein the groove and the projecting portion are formed in tapered shapes in which a width is decreased from a bottom side of the groove to an opening side of the groove.

7. The heat sink of claim 2, wherein a plurality of fixing holes aligned in a sliding direction of the heat dissipation unit are formed in one of the fixing unit and the heat dissipation unit,
one or more communication holes are formed in the other of the fixing unit and the heat dissipation unit to selectively communicate with one of the plurality of fixing holes according to a position where the heat dissipation unit is slid with respect to the fixing unit, and
fixing members are inserted into the fixing holes and the communication holes.

8. The heat sink of claim 7, wherein the fixing holes are screw holes formed in the fixing unit, and
the fixing members are screws which are inserted into the communication holes from a side of the heat dissipation unit and is screwed into the screw holes.

9. The heat sink of claim 1, wherein a pair of side wall portions are formed on one of the fixing unit and the heat dissipation unit to extend in a sliding direction of the heat dissipation unit along both side portions of the other of the fixing unit and the heat dissipation unit.

10. A substrate unit comprising:
a printed circuit board mounted with a heating element; and
a heat sink which includes a fixing unit fixed to the heating element and a heat dissipation unit, the heat dissipation unit including a heat dissipation protruding portion and configured to slide with respect to the fixing unit.

11. The substrate unit of claim 10, wherein a first heating element and a second heating element as the heating element are mounted on the printed circuit board,
a first heat sink is fixed to the first heating element, and the fixing unit of a second heat sink as the heat sink is fixed to the second heating element.

12. The substrate unit of claim 11, wherein an extension portion is formed in the first heat sink to extend a side of the heating element, and
the heat dissipation unit slides with respect to the fixing unit in a direction in which the extension portion extends.

13. The substrate unit of claim 12, wherein the heat dissipation unit includes a main body superimposed on the fixing unit, and
the heat dissipation protruding portion is formed on the main body at a side opposite to a side of the extension portion.

14. The substrate unit of claim 12, wherein the extension portion covers a part of the fixing unit.

15. The substrate unit of claim 12, wherein the heat dissipation unit includes a main body superimposed on the fixing unit,
the heat dissipation protruding portion is vertically provided on a surface of the main body at a side opposite to a side of the fixing unit, and
the extension portion is positioned at a higher position than the main body in a height direction of the second heat sink.

16. The substrate unit of claim 11, wherein the fixing unit of the second heat sink is fixed to the printed circuit board, together with the first heat sink through a common fixture.

17. The substrate unit of claim 11, wherein leg portions are formed on the fixing unit at both sides of the heating element and are vertically provided on the printed circuit board.

18. The substrate unit of claim 11, wherein the heat dissipation protruding portion is disposed to be offset in a direction in which the heat dissipation unit slides with respect to the heating element.

19. The substrate unit of claim 11, wherein the heat dissipation protruding portion overlaps with the heating element in a direction in which the heat dissipation unit slides.
